(19) United States
(12) Patent Application Publication
(10) Pub. No.: US 2024/0349510 A1
(43) Pub. Date: Oct. 17, 2024

(54) INTEGRATED CIRCUIT DEVICE WITH FERROELECTRIC CAPACITOR

(71) Applicant: Texas Instruments Incorporated, Dallas, TX (US)

(72) Inventors: Haowen Bu, Wylie, TX (US); Roger C. McDermott, Wylie, TX (US); Matthew Richards, Arlington, TX (US)

(21) Appl. No.: 18/479,006

(22) Filed: Sep. 30, 2023

Related U.S. Application Data
(60) Provisional application No. 63/459,802, filed on Apr. 17, 2023.

(51) Int. Cl. H10B 53/30

(52) U.S. Cl. CPC H10B 53/30; H01L 28/40

(57) ABSTRACT

A method forms an integrated circuit, by forming a first conductive member affixed relative to a semiconductor substrate and a second conductive member affixed relative to the semiconductor substrate. The method also forms a ferroelectric member between the first and second conductive members. The ferroelectric member has a first portion including a first atomic ratio of lead (Pb) relative to other materials in the first portion and a second portion including a second atomic ratio of lead relative to other materials in the second portion, the second atomic ratio differing from the first atomic ratio.

### CROSS-REFERENCE TO RELATED APPLICATION

This application claims the benefit of and priority to U.S. Provisional Application No. 63/459,802, filed Apr. 17, 2023, which is incorporated herein by reference.

### BACKGROUND

The described examples relate to semiconductor integrated circuits (IC) and fabrication, and more particularly, but not exclusively, to an IC that includes a ferroelectric capacitor.

Ferroelectric materials can be polarized and retain the polarization in the absence of an electrical field. As such, ferroelectric materials have been used or proposed for various apparatus, including by example in digital system memories, such as in a non-volatile memory known as a ferroelectric random access memory (FRAM). Such memories may be included in various types of computation systems, including embedded processors. In the FRAM, each storage cell includes one or more ferroelectric devices, in combination with other devices (e.g., a single or plural transistors). The ferroelectric device may include ferroelectric material between two electrodes, thereby forming a ferroelectric capacitor. The capacitor may be temporarily connected to, or between, a voltage source or voltage differential, to apply an electric field that will set the state of the device so long as the voltage exceeds a storage cell threshold voltage. The set state aligns dipoles in the ferroelectric cell and thereby sets a polarized data state, for example as a logic zero or one, and the state is maintained even after the voltage is removed. Thereafter, the state can be reversed if a sufficiently large and opposite electric field is applied, that is, by applying a voltage that exceeds the threshold voltage in the reverse direction.

A ferroelectric device such as described above may include lead (Pb) zirconate titanate (PZT). PZT provides favorable piezoelectric properties, including a high Curie temperature (the temperature below which proper binary operation is expected), spontaneous polarization, and a hysteresis response that provides some level of margin, that is difference, in the electrical field reversal amount that must be applied to switch the state of the PZT material and, correspondingly, a state of a PZT-implemented data cell. However, PZT deposition can be relatively slow, and PZT also may introduce other suboptimal device and fabrication aspects. Additionally, contemporary memories can have thousands or millions of such devices, so vulnerabilities in such devices may scale according to the number of devices in an IC, or on an IC wafer.

Accordingly, while the preceding has implementation in various prior art devices, this document provides examples that may improve on certain of the above concepts, as detailed below.

### SUMMARY

In an example, a method of forming an integrated circuit is described. The method forms a first conductive member affixed relative to a semiconductor substrate and a second conductive member affixed relative to the semiconductor substrate. The method also forms a ferroelectric member between the first and second conductive members. The ferroelectric member has a first portion including a first atomic ratio of lead relative to other materials in the first portion and a second portion including a second atomic ratio of lead relative to other materials in the second portion, the second atomic ratio differing from the first atomic ratio. Other aspects are also described and claimed.

### BRIEF DESCRIPTION OF THE DRAWINGS

FIGS. 1 through 8 are partial cross-sectional views representing successive fabrication stages and resultant structures of an IC semiconductor structure.

FIG. 9 is a wafer testing comparison chart using various processes to form IC FRAM cells.

FIG. 10 is an IC FRAM cell array.

FIG. 11 is a flow diagram of an example method for manufacturing a semiconductor structure.

### DETAILED DESCRIPTION

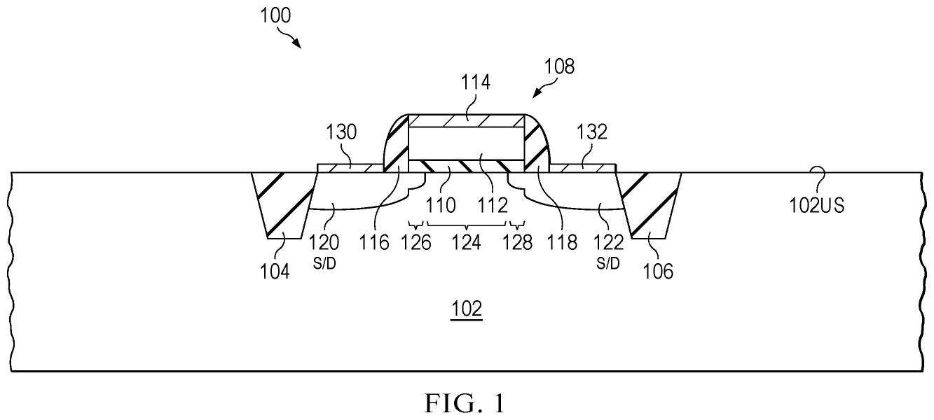

FIGS. 1 through 8 are cross-sectional views representing successive fabrication stages and resultant structures of a semiconductor structure 100. Ultimately, the semiconductor structure 100 will include a transistor and a ferroelectric cell, the latter being an electrical device including a ferroelectric material. As one example, the IC may provide a ferroelectric memory cell, including a transistor coupled to a ferroelectric capacitor. For example, details to such a structure are shown in co-owned U.S. Pat. No. 7,935,543, entitled “Method of Forming PZT Ferroelectric Capacitors for Integrated Circuits”, issued May 3, 2011, and hereby fully incorporated herein by reference. Alternatively, such a cell may include plural transistors and plural ferroelectric capacitors, whereby aspects illustrated below may be replicated or otherwise implemented to provide such plural structures. Still further, in addition to the transistor and ferroelectric capacitor, the IC may include numerous other devices (not shown) that function in relation to the devices that are illustrated below. Such devices may be isolated from the structures shown in FIG. 1 (and other later figures), for example via field oxides, formed for example using either a shallow trench isolation (STI) or local oxidation of silicon (LOCOS) process.

Starting with FIG. 1, the semiconductor structure 100 includes a semiconductor substrate 102, for example as part of a silicon wafer. Such a wafer typically includes multiple locations, each corresponding to a same or different IC on the wafer, so the illustration of FIG. 1 (and later figures) can be repeated in each wafer IC location. The wafer typically provides either a p-type or n-type semiconductor, and the substrate 102 can represent a portion of the bulk wafer or a region (e.g., a well or buried layer) formed in connection with the wafer. For FIG. 1 and various subsequent figures, the wafer, and its corresponding semiconductor substrate 102, is located in a wafer processing chamber, for purposes of atmosphere control, such as isolation, introduction of gases, and application of pressure/temperature, at selected durations. In previous process steps, isolating structures 104 and 106 have been formed into the substrate 102, from its upper surface 102US, and may be field oxides or other insulators. Thereafter, other structures have been formed between, or otherwise positioned relative to, the isolating structures 104 and 106. By way of example, one such structure is a planar transistor, having various portions/regions, as further described below.

Gate-related structures 108 have been formed atop the upper surface 102US. The gate-related structures 108 may include various items. For example, the gate-related structures 108 include a gate dielectric 110. The gate dielectric 110 may comprise various insulators, such as silicon dioxide, an oxynitride, a silicon nitride (SiN), any other high-dielectric material, or any combination or stack thereof. A gate 112 is formed over the gate dielectric 110. The gate 112 may comprise polycrystalline silicon (polysilicon), doped with either p-type or n-type dopants, either in-situ or in a later implant step(s). A conductive region 114 is formed along a surface (e.g., upper surface, in the perspective shown) of the gate 112. Subsequent electrical contact may be made to the conductive region 114, thereby also electrically coupling to the gate 112. The conductive region 114 may be a silicide or a metal (e.g., titanium, tungsten, titanium nitride (TiN), tantalum, TaN, or the like). Lastly, insulating gate sidewall spacers 116 and 118 are formed along respective sidewalls of portions of the gate dielectric 110 and gate 112. The insulating gate sidewall spacers 116 and 118 may be formed from forming (e.g., depositing) one or more layers and etching the layers, so as to provide spacing of various dopant implants relative to the sidewall surfaces of the gate 112.

Source/drain regions 120 and 122 (abbreviated S/D in the Figures) are formed within the substrate 102. The source/drain regions 120 and 122 provide a potential conductive path in an area (a channel 124) within the substrate 102 and between the regions 120 and 122. In the example, the source/drain regions 120 and 122 are symmetric so that one may serve as a source and the other a drain; alternative structures are contemplated, such as an extended drain region, but in any event there is a separate source and drain region. The source/drain regions 120 and 122 may be formed by implanting a same type of dopants for each, through the upper surface 102US, and positioned relative to the gate-related structures 108. For example, a respective portion 126 and 128 of each of the source/drain regions 120 and 122 is sometimes referred to as a lightly doped drain (LDD) region and may extend laterally under the respective sidewalls of the gate 112, which may be achieved by forming such regions after the gate 112 is formed but before the gate sidewall spacers 116 and 118 are formed. The remaining portions of the source/drain regions 120 and 122 are likewise formed using the same type of dopant as used for the portions 126 and 128, thereby in total forming the source/drain regions 120 and 122. A respective conductive region 130 and 132 is formed along a surface of each of the source/drain regions 120 and 122, for example as a silicide. Subsequent electrical contact may be made to each of the conductive regions 130 and 132, thereby also electrically coupling to the respective source/drain regions 120 and 122.

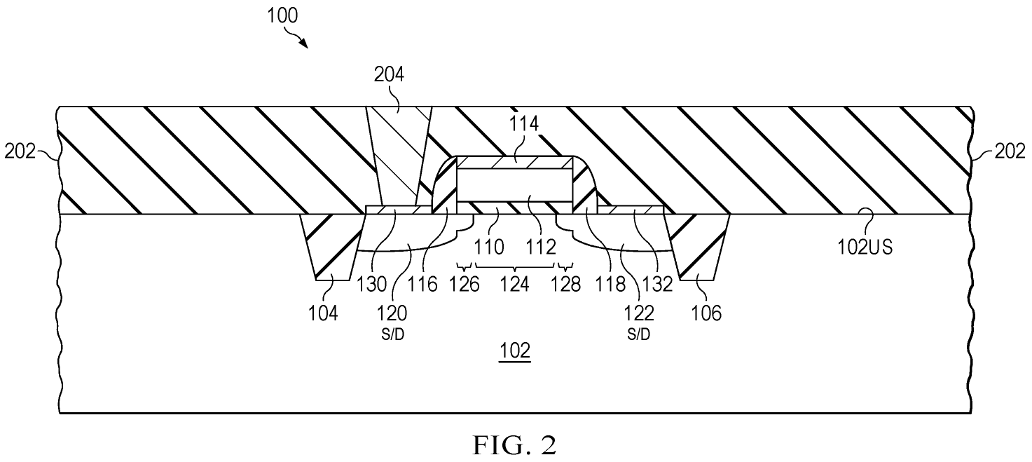

FIG. 2 illustrates additional structure over the FIG. 1 structures. A dielectric layer 202, for example comprising silicon dioxide, is formed along the upper surface 102US, and also along any structure at that surface. The dielectric layer 202 generally presents an upper planar surface, either when formed or by planarization. A conductive member 204 is formed through the dielectric layer 202 and in contact with the conductive region 130 for the source/drain region 120. For example, a void (or via) may be cut through the dielectric layer 202 and with a conductive material (e.g., metal) located within the void, with the resultant structure providing the conductive member 204. The conductive member 204 is sometimes referred to by particular terms, such as a via, contact, or plug. In any event, the conductivity of the conductive member 204 provides an electrical path between the source/drain region 120 and structure higher in the vertical dimension shown in FIGS. 1, 2, and other figures.

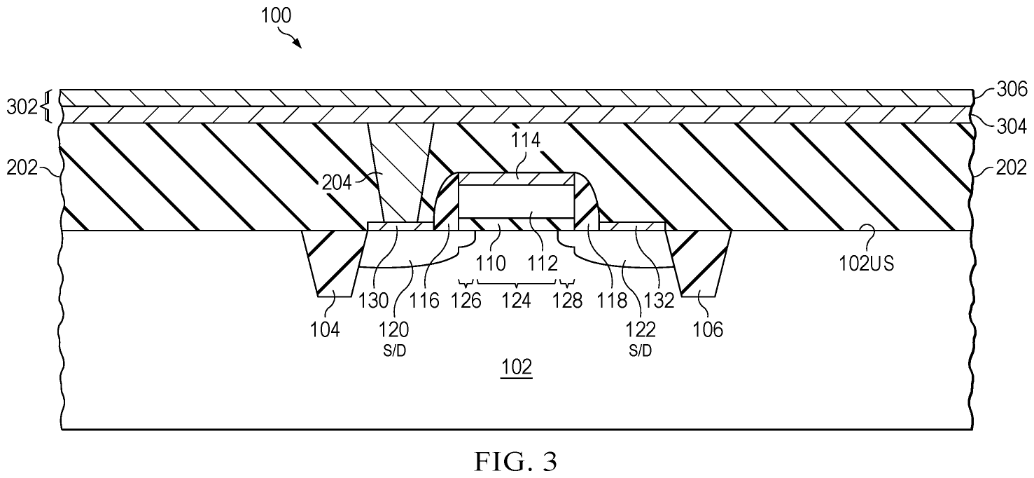

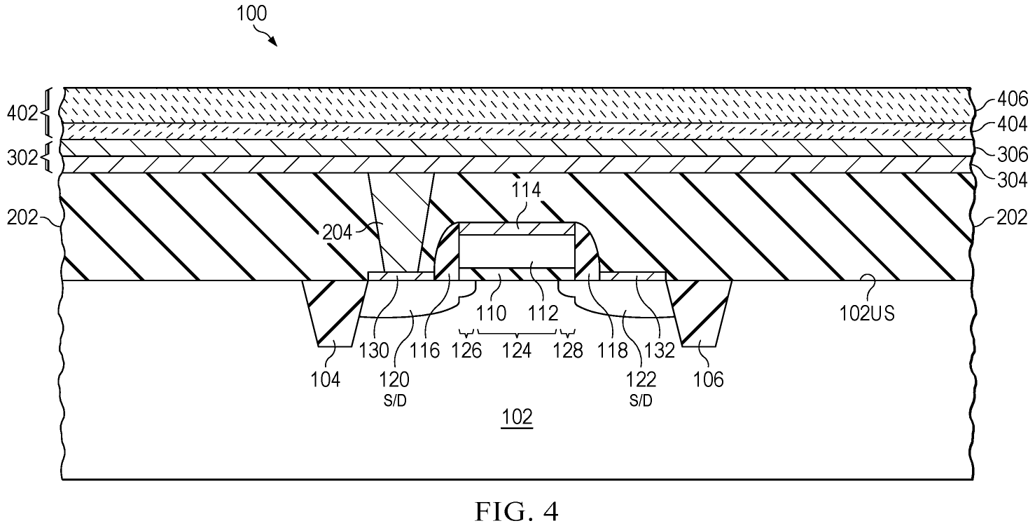

FIG. 3 illustrates additional structure over the FIG. 2 structures. A first electrode layer stack 302 is formed over the dielectric layer 202 and the conductive member 204. The first electrode layer stack 302 is so named as it is subsequently shaped (e.g., patterned and etched) to provide a first of two electrodes for a capacitive element. The first electrode layer stack 302 includes a first layer 304 atop the dielectric layer 202 and the conductive member 204, and a second layer 306 atop the first layer 304. Each of the first and second layers 304 and 306 is conductive, but may be of different materials. For example, the first layer 304 may include materials that provide a barrier layer, so as to reduce or prevent oxygen diffusion, and the first layer 304 may be reduced in thickness or eliminated if the second layer 306 is sufficiently thick. With the first layer 304 as both an oxygen barrier and conductive, it may include, for example, TiAlON, and have a thickness in a range from 20 nm to 60 nm. Also for example, the second layer 306 may be oxygen-stable in view of the anticipated conditions that will be subsequently imposed to form ferroelectric materials above the layer, as shown in FIG. 4. For example, the second layer 306 may comprise iridium (Ir). For either layer in the first electrode stack 302, other materials also may be used, for example as set forth in the above-incorporated U.S. Pat. No. 7,935,543.

FIG. 4 illustrates additional structure over the FIG. 3 structures. A variable-lead ferroelectric region 402 is formed over the first electrode layer stack 302. The variable-lead ferroelectric region 402 is so named as it includes a differing amount of lead in the vertical dimension, that is, generally perpendicular (e.g., at or within a few degrees from 90 degrees) from the longer dimension (major axis) of the first electrode layer stack 302. In the FIG. 4 illustrated example, the variable-lead ferroelectric region 402 includes a first layer 404 atop the first electrode stack 302, and a second layer 406 atop the first layer 404. Each of the first and second layers 404 and 406 includes a ferroelectric material, but the amount of lead concentration differs in the two layers. Further, each of the layers 404 and 406 also may include additional materials. In one example, the amount of lead in the first layer 404 is greater than in the second layer 406. For instance, each of the first layer 404 and the second layer 406 may include lead (Pb), zirconium (Zr), and titanium (Ti), and have a lead atomic ratio (Pb(AR)) according to the following Equation 1:

$$Pb ( AR ) = \frac{Pb}{\frac{Zr}{2} + Ti , 2} \qquad Equation 1$$

In Equation 1, each value, in the numerator, and in the denominator addends, is expressed as an atomic percent. Further, consistent with the above description of the relative lead concentration of the first and second layers 404 and 406, then the Pb(AR) of the first layer 404 exceeds the Pb(AR) of the second layer 406. The thicknesses of each of the first and second layers 404 and 406 may vary, for example with the thickness of the first layer 404 in a range from 5 nm to 30 nm (e.g., thickness of 8 nm), and with the thickness of the second layer 406 in a range from 40 nm to 100 nm (e.g., thickness of 65 nm).

The first and second layers 404 and 406 may be constructed in various manners. As one example, a respective process recipe is used for each of the layers 404 and 406, with the first layer 404 formed during a first time period T(1) and the second layer 406 formed during a second time period T(2). In both time periods T(1) and T(2), Pb, Zr, and Ti may be provided in liquid form (a precursor) and separately dissolved in organic solvents. The dissolved elements are flowed into a vaporizer, where they are converted to a vapor phase and then introduced into the reaction chamber where the wafer is located. For example, each liquid may be separately controlled to flow into a manifold having a nozzle output into the vaporizer for vaporization, where the manifold has the total liquid flow (that may include a carrier gas). Each dissolved material is controlled to separately flow at a respective flow rate (FR_Pb, FR_Zr, FR_Ti), which together combine for a total flow rate (FR_T). An inert carrier, such as octane (OC10), also may be introduced into the vaporizer (e.g., by the manifold) with its own flow rate (FR_OC10), so as to affect the FR_T, but not to be active in the in-chamber reaction. Other elements (e.g., oxygen) also may be present in the reaction chamber. Generally, the oxygen also may have a flow rate, for example remaining the same to form both layers 404 and 406 (or higher for layer 406) and at a rate from 3 to 7 liters per minute, but this flow rate is not intended to affect FR_T as described herein.

With the preceding considerations, in an example each of the Pb, Zr, and Ti flow (after dissolving with a respective organic solvent) into the wafer processing chamber during both of the two time periods T(1) and T(2). Also in an example, the wafer temperature is kept constant in both T(1) and T(2), for instance at a temperature from a range from 630° C. to 660° C., and for instance at 645° C., which may be a higher temperature than used in some alternative (e.g., baseline) processes. Still further, chamber pressure is reduced in T(2), relative to T(1), for example with T(1) pressure selected from a range from 1.8 to 2.2 torr (240-293 Pa), to T(2) pressure selected from a range from 1.1 to 1.5 torr (146-200 Pa). During T(2), the temperature of 645° C. and/or pressure reduction may reduce a potential for haze (e.g., PbO₂) to form during the processing reaction(s), as could otherwise occur, for example, due to reaction with wafer surface particles that may occur at lower temperatures or higher pressures. In T(1), each of the dissolved Pb, Zr, and Ti flows at a respective rate, and in addition OC10 is provided at a respective rate, for a total flow rate FR_T(1), of all four materials. The flow rates for each material, and other factors, are selected to achieve the relative differences described above, so as to achieve the desired lead atomic ratio Pb(AR). Accordingly, in T(1), the selections provide a resultant first lead atomic ratio Pb(AR(1)) in the created PZT film of the first layer 404, per Equation 1, based at least in part on the respective flow rates of Pb, Zr, and Ti. So, by way of example, FR_T(1)=1.1 ml/min. With these considerations, the resulting Pb(AR(1)) is in a range of 1.06≤ Pb(AR(1))≤1.08 (e.g., Pb(AR(1))=1.07). In T(2), each of the dissolved Pb, Zr, and Ti is flowed at a respective rate, and the OC10 flow rate is reduced or eliminated, for example for a total flow rate, FR_T(2), based on just the three active materials, and to provide a second atomic ratio Pb(AR(2)) in the PZT film of the second layer 406, where Pb(AR(2))<Pb(AR(1)). By way of example, 1.04≤ Pb(AR(2))≤1.06 (e.g., Pb(AR(2))=1.05). Accordingly, the relative Pb concentration in the second layer 406 is lower than in the first layer 404. Further, because the second layer 406 may be implemented with a lower Pb percentage, then the second layer 406 may be formed using a faster flow rate relative to that for the first layer 404, that is, FR_T(2)>FR_T(1). By way of example, FR_T(2)=1.5 ml/min. The faster speed will permit the lower Pb concentration to be formed, while also therefore completing the entirety of the variable-lead ferroelectric region 402, as compared to a region that is of a uniform and relatively high Pb concentration. In this manner, each semiconductor structure 100 may be constructed faster, increasing tool productivity, which is very desirable from a manufacturing standpoint.

From the above examples, the combination of the first and second layers 404 and 406 provides a variable-lead ferroelectric region 402, in which lead concentration is greater in the first layer 404 than in the second layer 406, as also represented in Pb(AR(1))>Pb(AR(2)). The relative concentration difference might be measured, for example, using x-ray fluorescence spectroscopy or using a D-SIMS depth profiling technique. As detailed later, the relative difference in lead within the variable-lead ferroelectric region 402 may provide one or more advantages in the finalized IC device. Such advantages may include, for example, providing a desirable PZT switched polarization, and corresponding switching margin, in a device (e.g., capacitor) that includes the variable-lead ferroelectric region 402, without unduly trading off an unacceptably high amount of leakage current through the device.

In another example, the variable-lead ferroelectric region 402 may include some other structure with a varying amount of Pb in the dimension perpendicular to the first electrode layer stack 302. For example, the variable-lead ferroelectric region 402 may include more than the two layers shown in FIG. 4. As another example, the variable-lead ferroelectric region 402 may include a gradient, for example wherein the largest concentration of Pb is closest to the first electrode layer stack 302, and in a direction away from the first electrode layer stack 302 the lead concentration remains above zero, but decreases (e.g., linearly or otherwise) relative to the largest Pb concentration position. A gradient approach, however, may in practical application present process complexities, for example if the gradient is sought by continuously changing gas flow so as to achieve the gradient. Accordingly, in practical (e.g., efficiently manufacturable) implementation, discrete layers may be formed, but the number of layers could be considerably greater than just two, and for example with each successive layer having a lesser lead concentration than a prior layer.

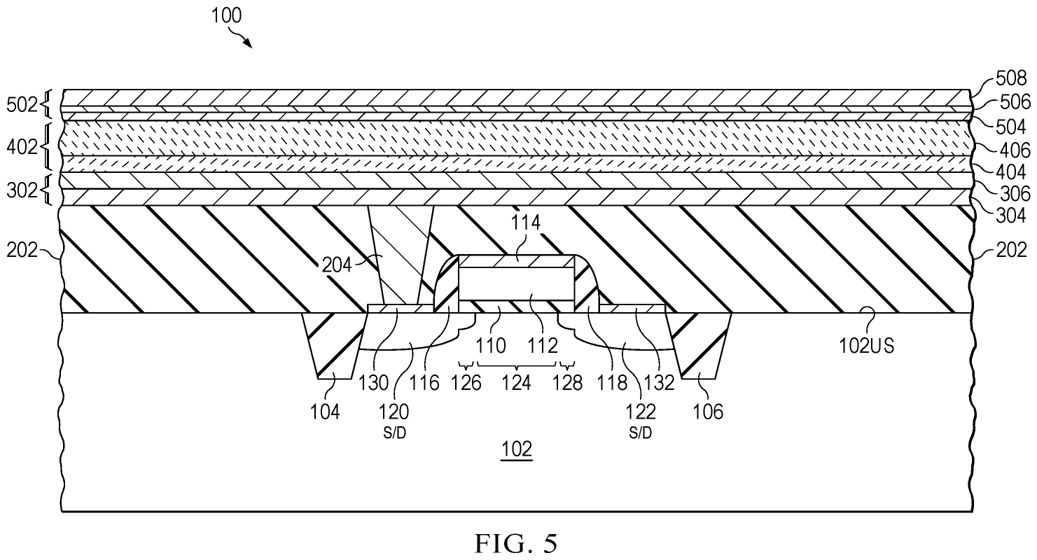

FIG. 5 illustrates additional structure over the FIG. 4 structures. A second electrode layer stack 502 is formed over the variable-lead ferroelectric region 402. The second electrode layer stack 502 is so named as it is subsequently shaped (e.g., patterned and etched) to provide a second of the two electrodes for the capacitive element. The second electrode layer stack 502 includes a first layer 504 atop the variable-lead ferroelectric region 402, a second layer 506 atop the first layer 504, and a third layer 508 atop the second layer 506. Each of the first, second, and third layers 504, 506, and 508 is conductive, but may be of different materials. For example, the first layer 504 may be a conductive oxide, such as IrO₂. Such materials may avoid fatigue degradation that may occur from long term read/write operations, where such degradation might occur if a noble metal were used. The second layer 506 may be a noble metal, such as Ir (or others), for example to maintain low contact resistance to the first layer 504 and to reduce the chance for oxidation between the first and second layers 504 and 506 during subsequent high temperature processing. The third layer 508 also includes a metal for conductive properties, but further includes a material so as to serve as a hard mask for a subsequent etch. As an example, the third layer 508 may be TiAlON (or a stack, including TiAlON/TiAIN/TiAl). As an example, the first layer 504 may range in thickness from 20 nm to 50 nm, the second layer 506 may range in thickness from 10 nm to 50 nm, and the third layer 508 may range in thickness from 150 nm to 400 nm. Lastly, for any layer in the second electrode stack 502, other materials also may be used, for example as set forth in the above-incorporated U.S. Pat. No. 7,935,543.

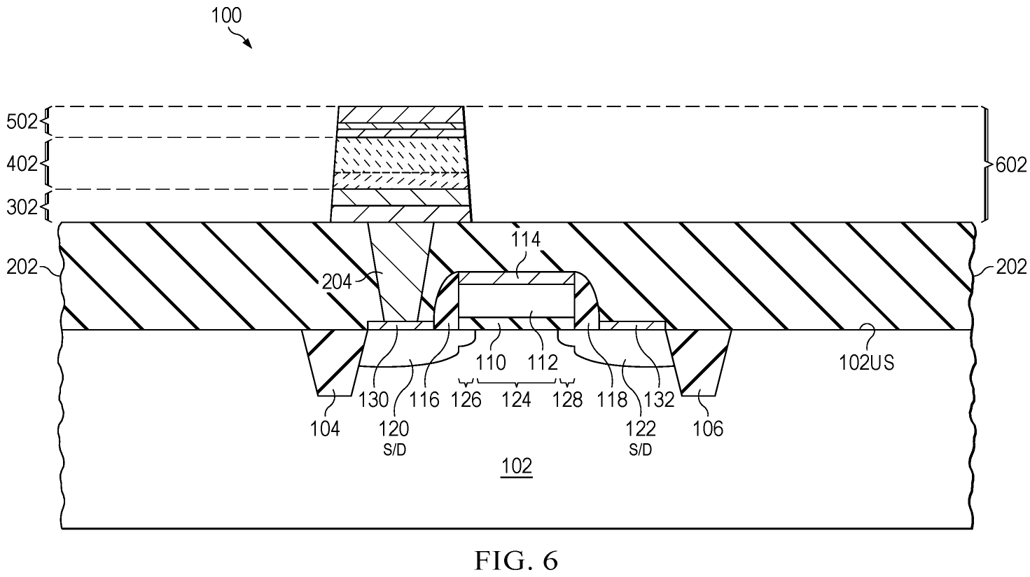

FIG. 6 illustrates a reduced structure from FIG. 5, for example after a pattern and etch. Specifically, a mask layer (e.g., photoresist, not shown) is formed over the FIG. 5 structures, with an appropriate opening so that a subsequent etch removes laterally-positioned portions of each etched layer, while leaving more centrally-located portions of each etched layer so as to provide a capacitive element 602. Accordingly, the capacitive element 602 includes the post-etch remaining portions of the first electrode stack 302, the variable-lead ferroelectric region 402, and the second electrode stack 502. These portions, including conductive materials from the first and second electrode stacks 302 and 502, and the ferroelectric material from the variable-lead ferroelectric region 402 between those stacks, together provide a first conductive member, a second conductive member, and a ferroelectric material between them, hence being identified as the capacitive element 602. The capacitive element 602 may have inclined sidewalls, for example due to certain processing steps (e.g., plasma etch and/or wet solvent clean). Further, given the above-described formation of the first and second layers 404 and 406, it should be appreciated that the capacitive element 602 includes a resultant ferroelectric member between the first and second conductive electrode stacks, whereby the ferroelectric member includes a nonuniform lead profile in the dimension extending from the first electrode to the second electrode.

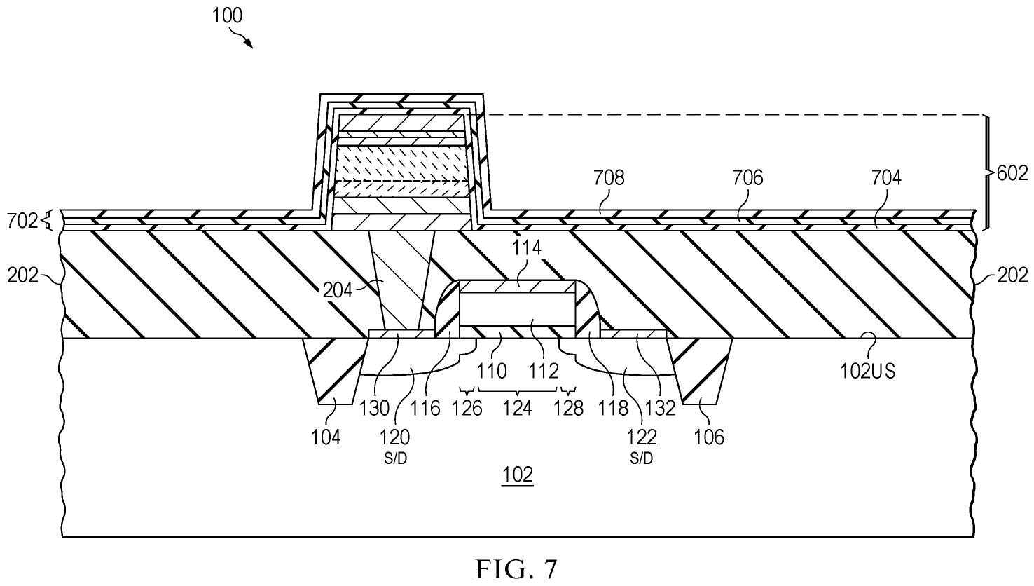

FIG. 7 illustrates additional structure over the FIG. 6 structures. An encapsulating region 702 is formed over the capacitive element 602, for example to protect the capacitive element 602 from potential degradation during subsequent processing steps. In an example, the encapsulating region 702 includes plural layers. For instance, the encapsulating region 702 can include a first layer 704 formed atop the dielectric layer 202 and the capacitive element 602, a second layer 706 formed atop the first layer 704, and a third layer 708 formed atop the second layer 706. By example: (i) the first layer 704 may be aluminum oxide (AlOₓ), of a thickness from 15 nm to 50 nm; (ii) the second layer 706 may be SiNₓ, for example formed using high-density plasma (HDP) deposition, of a thickness from 30 nm to 80 nm; and (iii) the third layer 708 also may be SiNₓ, but in the form of plasma enhanced chemical deposition (PECVD) SiNₓ, of a thickness from 30 nm to 80 nm. Any one or more of the encapsulating region 702 layers may protect the crystal structure of the capacitive element 602, for example impeding its penetrability to other atoms (e.g., hydrogen), which if introduced into the structure could impede the ability of the structure to flex in response to an electric field, which otherwise could reduce the ferroelectric (or piezoelectric) nature or functionality of the device.

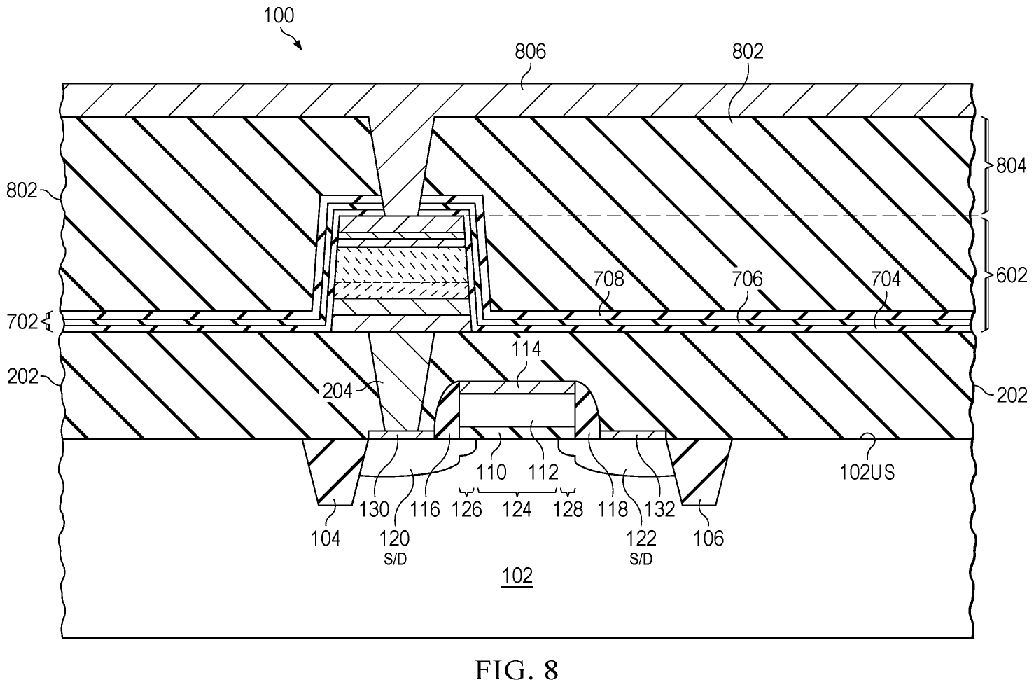

FIG. 8 illustrates additional structure over the FIG. 7 structures. A dielectric layer 802, for example comprising silicon dioxide, is formed along the FIG. 7 encapsulating region 702, so more specifically over the third layer 708. The dielectric layer 802 generally presents an upper planar surface, either when formed or by planarization. While not shown, a mask is then placed atop the dielectric layer 802, with an opening vertically aligned over the top of the capacitive element 602, and an etch is performed through the dielectric layer 802, and through the first, second, and third layers 704, 706, and 708, to the top of the second electrode layer stack 502 (see FIG. 6). Further, recall that the top of the second electrode layer stack 502 is provided by the third layer 508, which from FIG. 8 is more readily understood in its functional as a hard mask to the FIG. 8 etch. Thereafter, a conductive member 804 is formed through the opening that was formed in the dielectric layer 802 and in contact with the top of the second electrode layer stack 502. For example, the conductive member 804 may be part of a metal layer 806, sometimes referred to as metal-1 and that may include a metal or metals such as copper or aluminum, or the conductive member 804 may be first formed and, thereafter, the metal layer 806 is formed in contact with the conductive member 804. In any event, the conductive member 804 provides an electrical path between the metal layer 806 and the second electrode layer stack. Accordingly, the capacitive element 602, as encapsulated by the encapsulating region 702, is electrically connected between the metal layer 806 and the source/drain region 120 of the planar transistor formed in connection with the substrate 102.

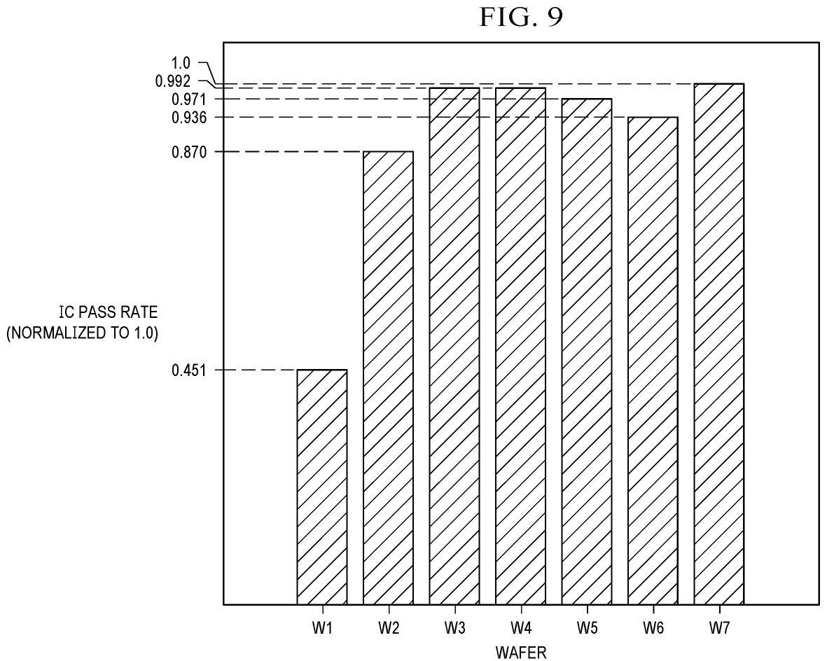

FIG. 9 is a wafer testing comparison chart using various processes to form IC FRAM cells, as compared to a baseline process. More particularly, the FIG. 9 horizontal axis indicates a total of seven wafers, designated W1, W2, . . . , W7, each having a same number of FRAM cell ICs, for example with over 100 ICs per wafer. The FIG. 9 vertical axis indicates a pass rate for the total number of ICs, per wafer, that passed a particular test as applied to all wafers. The pass rate is normalized to a value of 1.0, that is, the most successfully tested wafer (wafer W7) is deemed to provide a pass rate of 1.0. With respect to particular testing, one applicable test for FRAM cell ICs is to confirm the sufficiency of the capacitive element hysteresis or switched polarization margin, that is, whether the element will properly switch between data states at a tested reversal of voltage at a particular level (e.g., 600 mV). Applying such an example to FIG. 9, the wafer W1 represents a baseline wafer for which the FRAM cell in each wafer IC is formed having a capacitive cell with a uniform amount of lead throughout its ferroelectric material. With these conditions, the wafer W1 has a pass rate, normalized to a value of 1.0, equal to 0.451. In contrast, each of the wafers W2 through W7 correspond to wafers having FRAM cell ICs formed according to the examples described above, that is with a variable-lead ferroelectric region in the capacitive call of the FRAM, and also with some other process variation(s) as between each of the wafers W2 through W7. For example, such variations may obtain different values of Pb(AR) in each of the first and second layers 404 and 406, while still achieving in each instance for the wafers W2 through W7, a relative lead concentration such that Pb(AR(2))<Pb(AR(1)). FIG. 9 demonstrates that the pass rate for all of the wafers W2 through W7 is remarkably increased versus that of wafer W1, with the wafers W3 through W7 more than doubling the pass rate of the baseline wafer W1. Accordingly, examples provided herein are expected to provide vastly improved performance over certain baseline approaches.

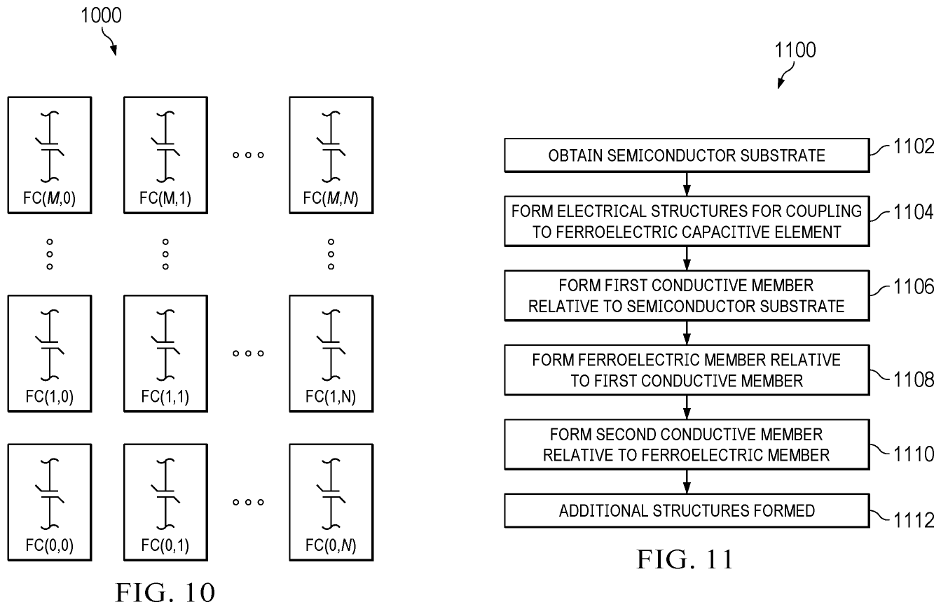

FIG. 10 is a block diagram of an example IC 1000. The IC 1000 represents a single IC, as may be replicated numerous times on a wafer, such as those described above. The IC 1000 includes an integer number of FRAM cells, shown by example as the product (M+1)×(N+1) corresponding to two integers, M and N. Particularly, in the illustrated example, the FRAM cells are arranged in an array, having N+1 rows and M+1 columns, with each cell designated as FC(m,n). Further, each cell is shown to include at least one ferroelectric capacitive element, as may be implemented and/or connected as described earlier, or in other forms. Each of those capacitive elements includes a variable-lead ferroelectric region 402 and, accordingly, may provide benefits consistent with the above descriptions (and illustration of FIG. 9).

FIG. 11 is a flow diagram of an example method 1100 that summarizes various of the above-described steps for manufacturing the semiconductor structure 100, for example as shown in FIG. 8. The flow diagram 1100 begins in a step 1102, in which the FIG. 1 semiconductor substrate 102 is obtained. The semiconductor substrate 102, at this stage, may be a bare wafer or may have one or more semiconductor features already formed on it. The semiconductor substrate 102 also includes one or more areas, or on one or more electrical structures adjacent to such an area, in which it is desirable to form a ferroelectric capacitive element. Next, in a step 1104, electrical structure is formed to which a ferroelectric capacitive element will be coupled. For example, such electrical structure can include a planar transistor, as shown in FIG. 1, and also an electrical coupling (or plural couplings) to parts of the transistor, as shown in FIG. 2. Next, in a step 1106, a first conductive member is affixed relative to the semiconductor substrate 102. For example, the first conductive member may be formed as a FIG. 3 first electrode layer stack 302. Next in a step 1108, a ferroelectric member is formed relative to the first conductive member. For example, the ferroelectric member may be formed as a FIG. 4 variable-lead ferroelectric region 402, formed over the first electrode layer stack 302. Different areas of the ferroelectric member have respective differing lead atomic ratios. Next, in a step 1110, a second conductive member is affixed relative to the ferroelectric member. For example, the second conductive member may be formed as a FIG. 5 second electrode layer stack 502. After step 1110, as shown generally in a step 1114, additional structures may be formed, in connection with the transistor, ferroelectric member, and interconnections to these and other devices associated with the step 1002 semiconductor substrate.

From the above, one skilled in the art will appreciate that examples are provided for semiconductor IC fabrication, for example with respect to an IC that includes a ferroelectric capacitor. Such examples provide various benefits, some of which are described above and including still others. For example, examples may implement a ferroelectric capacitor, a ferroelectric capacitor cell, a number of such cells, and a number of ICs on a wafer with each IC having such cells. At least one variable-lead ferroelectric region portion(s) of the cell provides at least some volume in which lead is relatively high, which may provide improved consistency in switch polarization. At least one other variable-lead ferroelectric region portion(s) of the cell provides at least some volume in which lead is relatively low, which can desirably reduce leakage current in the capacitive device. Reduced leakage current may increase wafer yield, particularly as compared to other devices in which leakage between capacitive element electrodes renders a device unusable for the marketplace. Further, traditional lead processes may include some variability, for example changes of lead concentration in a lead canister, process drift, lifespan of other process parts, shower head temperature, and the like, any of which can impact the realized amount of lead in a ferroelectric element. Such variability can render an unpredictable end product, thereby lowering yield due to missing a narrow target window required in certain prior approaches to achieve sufficient margin and limited leakage current. In contrast, examples described herein may be more tolerant to such variability. Still further, such cells may be manufactured by a process that forms a variable-lead ferroelectric region portion of the cell at two different rates, where a faster of the two rates allows the cell to be completed faster than if the cell were formed only at the slower rate, thereby increasing production time for not just the cell, but for the IC and the wafer that includes the IC. The expedited rate applies across all similarly-situated wafers, which increases wafer and ultimately singulated IC throughput. These benefits may be realized for more complex structures, or for multiple devices on the same substrate (and IC), thereby realizing scaled improvement across the device. Still additional modifications are possible in the described examples. For example, from time to time throughout the above description, as may also be referred to in a claim or claims, a layer or structure may be described as being of a substance such as “aluminum,” “tungsten,” “copper,” “silicon nitride,” etc. These descriptions are to be understood in context and as they are used in the semiconductor manufacturing industry. For example, in the semiconductor industry, when a metallization layer is described as being aluminum, it is understood that the metal of the layer comprises elemental aluminum as a principal component, but the elemental aluminum may be, and typically is, alloyed, doped, or otherwise impure. As another example, while a ferroelectric including Pb, Zr, and Ti has been described, other ferroelectric compounds may be used, for example such as PbZnNb and PbMgNb. As another example, SiN may be a silicon rich SiN or a nitrogen rich SiN. SiN nitride may contain some oxygen, but not so much that the material's dielectric constant is substantially different from that of high purity stoichiometric SiN. Accordingly, these and prior examples demonstrate that still others are within the scope of the following claims.

What is claimed is:

1. A method of forming an integrated circuit, comprising:
forming a first conductive member affixed relative to a semiconductor substrate;
forming a second conductive member affixed relative to the semiconductor substrate; and
forming a ferroelectric member between the first and second conductive members, the ferroelectric member having a first portion including a first atomic ratio of lead (Pb) relative to other materials in the first portion and a second portion including a second atomic ratio of lead relative to other materials in the second portion, the second atomic ratio differing from the first atomic ratio.

2. The method of claim 1 wherein the first portion provides a first layer of material.

3. The method of claim 2 wherein the second portion provides a second layer of material.

4. The method of claim 3 wherein the first atomic ratio is greater than the second atomic ratio, and wherein the first layer has a thickness from 5 nm to 30 nm.

5. The method of claim 3 wherein the first atomic ratio is greater than the second atomic ratio, and wherein the first layer has a thickness less than a thickness of the second layer.

6. The method of claim 3 wherein the ferroelectric member includes lead, zirconium, and titanium, and wherein each of the first and second lead atomic ratio is a ratio of lead relative to at least zirconium and titanium.

7. The method of claim 6 wherein the first atomic ratio is in a range from 1.06 to 1.08 and wherein the second atomic ratio is in a range from 1.04 to 1.06.

8. The method of claim 3 wherein the step of forming a ferroelectric member forms the first layer of material at a first flow rate and forms the second layer of material at a second flow rate different than the first flow rate.

9. The method of claim 8 wherein a faster of the first flow rate and the second flow rate is at least 1.5 ml/min.

10. The method of claim 8 wherein a faster of the first flow rate and the second flow rate is from 1.5 ml/min to 2.5 ml/min.

11. The method of claim 1 wherein the first portion and the second portion provide a lead gradient between the first and second conductive members.

12. The method of claim 1 wherein the ferroelectric member includes lead, zirconium, and titanium.

13. The method of claim 1 and further comprising:
forming a transistor relative to the semiconductor substrate, the transistor having at least a first source/drain region in a portion of the semiconductor substrate; and
forming a conductive path from the first source/drain region to one of the first conductive member or the second conductive member.

14. The method of claim 1 and further comprising:
forming the first conductive member affixed at a first distance relative to the semiconductor substrate;
forming the second conductive member affixed at a second distance, greater than the first distance, relative to the semiconductor substrate; and
forming the ferroelectric member having a greater lead concentration closer to the first conductive member as compared to closer to the second conductive member.

15. The method of claim 1 and further comprising forming a plurality of cells relative to the semiconductor substrate, wherein the step of forming a first conductive member includes forming a first conductive member for each cell in the plurality of cells, wherein the step of forming a second conductive member includes forming a second conductive member for each cell in the plurality of cells, and wherein the step of forming a ferroelectric member includes forming a ferroelectric member for each cell in the plurality of cells.

16. An integrated circuit, comprising:
a first conductive member affixed relative to a semiconductor substrate;
a second conductive member affixed relative to the semiconductor substrate; and
a ferroelectric member between the first and second conductive members, the ferroelectric member including a nonuniform lead profile in a dimension extending from the first conductive member to the second conductive member.

17. The integrated circuit of claim 16, wherein the first conductive member is affixed at a first distance closer to an upper surface of the semiconductor substrate, as compared to a second distance between the upper surface and the second conductive member, and wherein the ferroelectric member has a greater lead concentration closer to the first conductive member as compared to closer to the second conductive member.

18. The integrated circuit of claim 17 wherein the ferroelectric member includes plural layers, wherein each layer in the plural layers has a differing lead concentration from at least one other layer in the plural layers.

19. The integrated circuit of claim 17 wherein the ferroelectric member includes plural layers, wherein a first layer in the plural layers has the greater lead concentration, and wherein the first layer has a thickness in a range from 5 nm to 30 nm.

20. The integrated circuit of claim 16 and further comprising a transistor coupled to at least one of the first conductive member and the second conductive member.
